(19) United States
(12) Patent Application Publication
(10) Pub. No.: US 2006/0125559 A1
(43) Pub. Date: Jun. 15, 2006

(54) Method of enhancing power amplifier linearity

(76) Inventors: Uri Garbi, Rosh Ha'ain (IL); Nir Sasson, Ein Sarid (IL); Adam Lapid, Shoham (IL)

Correspondence Address: TEXAS INSTRUMENTS INCORPORATED, P O BOX 655474, M/S 3999, DALLAS, TX, 75265, US

(21) Appl. No.: 11/012,796

(22) Filed: Dec. 15, 2004

(51) Int. Cl. H03F 1/26

(52) U.S. Cl. 330/149; 330/2

(57) ABSTRACT

A method of enhancing power amplifier linearity includes steps to ensure power amplifier spectral purity in cable broadband environments as well as in other RF environments. The technique employed may be either non-decision directed or decision directed. The non linearity products are canceled by processing the signal before it is introduced to the power amplifier, using an open or closed loop to estimate the non-linear coefficients of the amplifier transfer function polynomial. The inverse polynomial is then constructed; and the signal is applied to this inverse polynomial. The output of this operation is fed into the amplifier (subsequent to digital to analog conversion). The foregoing signal processing along with the amplifier parameters results in a reduction of harmonics and intermodulation products.

### BACKGROUND OF THE INVENTION

1. Field of the Invention

This invention relates generally to cable broadband and other radio frequency (RF) environments, and more particularly to a method of enhancing power amplifier linearity to ensure power amplifier spectral purity in such environments.

2. Description of the Prior Art

High power RF signals are often required to be transmitted in cable broadband environments as well as in other RF environments. The spectral purity around the transmitted signal must be high in order to avoid interference to other users in multiple access environments. The limited linearity of the power amplifier might impair the spectral purity due to intermodulation products as well as harmonics of the desired signal. Further, linearity requires power consumption to be higher, also introducing system limitations.

In view of the foregoing, it is highly desirable and advantageous to provide a method of enhancing power amplifier linearity to ensure power amplifier spectral purity in cable broadband environments as well as in other RF environments.

### SUMMARY OF THE INVENTION

The present invention is directed to a method of enhancing power amplifier linearity to ensure power amplifier spectral purity in cable broadband environments as well as in other RF environments. The technique employed may be either non-decision directed or decision directed. The non linearity products are canceled by processing the signal before it is introduced to the power amplifier, using an open or closed loop to estimate the non-linear coefficients of the amplifier transfer function polynomial. The inverse polynomial is then constructed; and the signal is applied to this inverse polynomial. The output of this operation is fed into the amplifier (subsequent to digital to analog conversion). The foregoing signal processing along with the amplifier parameters results in a reduction of harmonics and intermodulation products.

According to one embodiment, a method of enhancing power amplifier linearity comprises the steps of:

applying an input signal to a power amplifier and generating a digitized output signal there from;

observing second and third order harmonics of the digitized output signal;

extracting coefficients associated with harmonics less than fourth order;

applying the extracted coefficients to an inverse non-linear function associated with the digitized output signal and generating an inverse non-linear function output signal there from;

converting the inverse non-linear function output signal to an analog signal; and

applying the analog signal into the power amplifier and generating an amplified output signal there from such that second and third order harmonics are substantially eliminated.

According to another embodiment, a method of enhancing power amplifier linearity comprises the steps of:

applying two distinct tone signals to a power amplifier and generating digitized output signals there from;

observing second and third order intermodulation products associated with the digitized output signals;

extracting coefficients associated with the second and third order intermodulation products;

applying the extracted coefficients to an inverse non-linear function associated with the digitized output signal and generating an inverse non-linear function output signal there from;

converting the inverse non-linear function output signal to an analog signal; and

applying the analog signal into the power amplifier and generating an amplified output signal there from such that second and third order intermodulation products are substantially eliminated.

According to yet another embodiment, a method of enhancing power amplifier linearity comprises the steps of:

applying an input signal to a power amplifier and generating a digitized output signal there from;

passing the digitized output signal through an inverse non-linear function signal processor and generating a feedback signal having harmonics less than fourth order there from;

converting the feedback signal to an analog signal; and

subtracting the feedback signal from the power amplifier input signal and generating an amplified output signal there from such that second and third order harmonics are substantially eliminated.

According to still another embodiment, a method of enhancing power amplifier linearity comprises the steps of:

applying a two-tone input signal to a power amplifier and generating a digitized output signal there from;

passing the digitized output signal through an inverse non-linear function signal processor and generating a feedback signal having intermodulation products less than fourth order there from;

converting the feedback signal to an analog signal; and

subtracting the feedback signal from the power amplifier input signal and generating an amplified output signal there from such that second and third order intermodulation products are substantially eliminated.

According to still another embodiment, a method of enhancing power amplifier linearity comprises processing an input signal to the power amplifier such that non-linearity products associated with the power amplifier transfer function are substantially canceled prior to application of the input signal to the power amplifier.

### BRIEF DESCRIPTION OF THE DRAWINGS

Other aspects and features of the present invention and many of the attendant advantages of the present invention will be readily appreciated as the invention becomes better understood by reference to the following detailed description when considered in connection with the accompanying drawings in which like reference numerals designate like parts throughout the figures thereof and wherein:

FIG. 1 is a flow diagram illustrating one method of reducing harmonic amplifier transmissions according to one embodiment of the present invention;

FIG. 2 is a flow diagram illustrating one method of reducing intermodulation products from amplifier transmissions according to one embodiment of the present invention;

FIG. 3 is a flow diagram illustrating another method of reducing harmonic amplifier transmissions; and

FIG. 4 is a flow diagram illustrating another method of reducing intermodulation products from amplifier transmissions.

While the above-identified drawing figures set forth alternative embodiments, other embodiments of the present invention are also contemplated, as noted in the discussion. In all cases, this disclosure presents illustrated embodiments of the present invention by way of representation and not limitation. Numerous other modifications and embodiments can be devised by those skilled in the art which fall within the scope and spirit of the principles of this invention.

### DETAILED DESCRIPTION OF THE PREFERRED EMBODIMENTS

Non-linear amplifier products are canceled, as stated herein before, by processing the amplifier input signal before it is introduced to the power amplifier, using an open or closed loop to estimate the non-linear coefficients of the amplifier transfer function polynomial. The inverse polynomial is then constructed; and the signal is applied to this inverse polynomial. The output of this operation is fed into the amplifier (subsequent to digital to analog conversion). The foregoing signal processing along with the amplifier parameters results in a reduction of harmonics and intermodulation products.

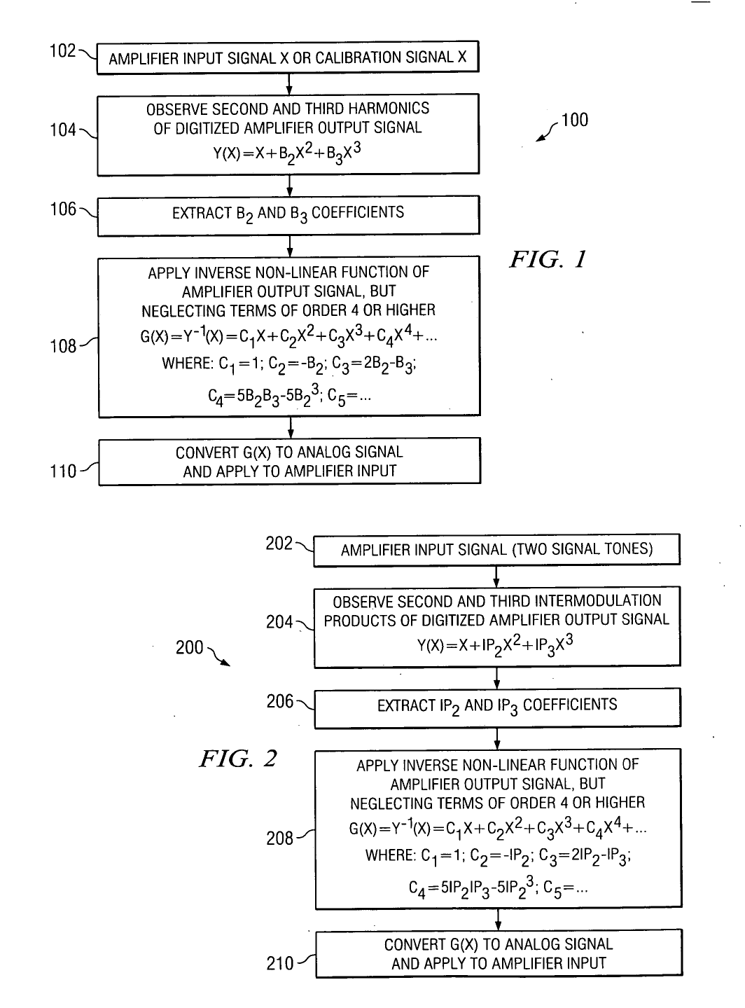

FIG. 1 is a flow diagram illustrating one method 100 of reducing harmonic amplifier transmissions according to one embodiment of the present invention. Method 100 assumes the signal Y at the output of the amplifier, prior to the convergence of an algorithm as suggested via the present method, is a distorted version of the input signal X:
Y(X)=X+B₂X²+B₃X³,
assuming the linear amplifier gain is normalized to 1.

In order to converge the inverse non-linear function, it is possible to use either the transmitted desired signal, X, or a dedicated calibration signal that can be, for example, either single or two tone. The inverse function of the above polynomial is:
G(X)=Y⁻¹(X)=C₁X+C₂X²+C₃X³+ . . . ,
where:
C₁=1,
C₂=−B₂,
C₃=2B₂²−B₃,
C₄=5B₂B₃−5B₂³, and
C₅=. . . .
Thus:
G(X)=Y⁻¹(X)=X−B₂X²+(2B₃²−B₃)X³+0(X⁴, X⁵, X⁶, . . . ).

The present inventors discovered that terms of order 4 or higher can be neglected, as they were both out of the range of interest, and much weaker. Given the foregoing inverse function G(X), it remains to estimate B₂ and B₃.

One technique for utilizing a calibration signal is now described in more detail herein below, and includes the following steps:
1) inject a single tone 102,
2) observe the 2^{nd} harmonic of the digitized Y(X), as shown in block 104,
3) observe the 3^{rd} harmonic of the digitized Y(X), as shown in block 106,
4) extract the B₂ and B₃ coefficients, as shown in block 108, and
5) apply the inverse non-linear function G(X), as shown in block 110.

The non-linear function G(X) is then first converted to an analog signal prior to its application to the amplifier input, as shown in block 110. This technique can, for example, be implemented once during power-up, or during normal operation.

A similar scheme can be implemented using two-tone injection, and observation of 3^{rd} order intermodulation products (e.g. by measuring IP2 and IP3 from the desired signal and the second and third order intermodulation products).

The present invention is not so limited however, and those skilled in the art will readily appreciate the principles described herein can be implemented using a decision directed solution, although at the additional expense of higher complexity.

FIG. 2 is a flow diagram illustrating another method 200 of reducing intermodulation products from amplifier transmissions according to one embodiment of the present invention. Similar to method 100, method 200 assumes the signal Y at the output of the amplifier, prior to the convergence of an algorithm as suggested via the present method, is a distorted version of the input signal X.

One technique for utilizing two signal tones to reduce intermodulation products from amplifier transmissions is now described in more detail herein below, and includes the following steps:
1) inject two distinct signal tones 202,
2) observe the 2^{nd} intermodulation product of the digitized Y(X), as shown in block 204,
3) observe the 3^{rd} intermodulation product of the digitized Y(X), also as shown in block 204,
4) extract the intermodulation product IP₂ and IP₃ coefficients, as shown in block 206, and
5) apply the inverse non-linear function G(X), as shown in block 208.

The non-linear function G(X) is then first converted to an analog signal prior to its application to the amplifier input, as shown in block 210. This technique can, for example, similarly be implemented once during power-up, or during normal operation.

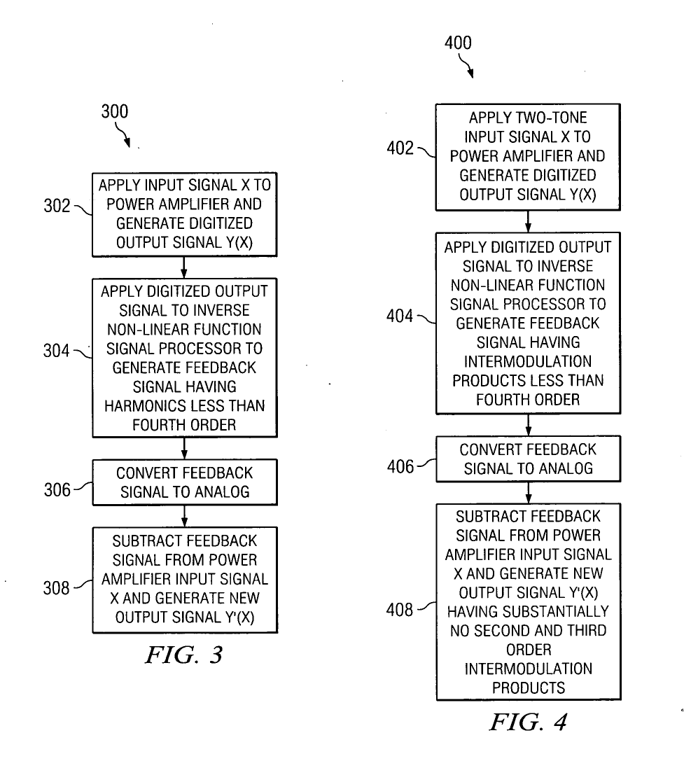

Looking now at FIG. 3, a flow diagram illustrates another method 300 of reducing harmonic amplifier transmissions. Unlike methods 100 and 200 described herein before, method 300 employs a decision directed technique and includes the steps of:

1) applying an input signal to a power amplifier and generating a digitized output signal there from, as shown in block 302;

2) passing the digitized output signal through an inverse non-linear function signal processor and generating a feedback signal having harmonics less than fourth order there from, as shown in block 304;

3) converting the feedback signal to an analog signal, as shown in block 306; and

4) subtracting the feedback signal from the power amplifier input signal and generating an amplified output signal there from such that second and third order harmonics are substantially eliminated, as shown in block 308.

FIG. 4 is a flow diagram illustrating yet another method of reducing intermodulation products from amplifier transmissions. Method 400 also employs a decision directed technique and includes the following steps:

1) applying a two-tone input signal to a power amplifier and generating a digitized output signal there from, as shown in block 402;

passing the digitized output signal through an inverse non-linear function signal processor and generating a feedback signal having intermodulation products less than fourth order there from, as shown in block 404;

converting the feedback signal to an analog signal, as shown in block 406; and

subtracting the feedback signal from the power amplifier input signal and generating an amplified output signal there from such that second and third order intermodulation products are substantially eliminated, as shown in block 408.

In view of the above, it can be seen the present invention presents a significant advancement in the art of broadband noise reduction. This invention has been described in considerable detail in order to provide those skilled in the cable broadband and radio frequency arts with the information needed to apply the novel principles and to construct and use such specialized components as are required. In view of the foregoing descriptions, it should be apparent that the present invention represents a significant departure from the prior art in construction and operation. However, while particular embodiments of the present invention have been described herein in detail, it is to be understood that various alterations, modifications and substitutions can be made therein without departing in any way from the spirit and scope of the present invention, as defined in the claims which follow.

What is claimed is:

1. A method of enhancing power amplifier linearity, the method comprising the steps of:
applying an input signal to a power amplifier and generating a digitized output signal there from;
observing second and third order harmonics of the digitized output signal;
extracting coefficients associated with harmonics less than fourth order;
applying the extracted coefficients to an inverse non-linear function associated with the digitized output signal and generating an inverse non-linear function output signal there from;
converting the inverse non-linear function output signal to an analog signal; and
applying the analog signal-into the power amplifier and generating an amplified output signal there from such that second and third order harmonics are substantially eliminated.

2. A method of enhancing power amplifier linearity, the method comprising the steps of:
applying two distinct signal tones into a power amplifier and generating digitized output signals there from;
observing second and third order intermodulation products associated with the digitized output signals;
extracting coefficients associated with the second and third order intermodulation products;
applying the extracted coefficients to an inverse non-linear function associated with the digitized output signal and generating an inverse non-linear function output signal there from;
converting the inverse non-linear function output signal to an analog signal; and
applying the analog signal into the power amplifier and generating an amplified output signal there from such that second and third order intermodulation products are substantially eliminated.

3. A method of enhancing power amplifier linearity, the method comprising the steps of:
applying an input signal to a power amplifier and generating a digitized output signal there from;
passing the digitized output signal through an inverse non-linear function signal processor and generating a feedback signal having harmonics less than fourth order there from;
converting the feedback signal to an analog signal; and
subtracting the feedback signal from the power amplifier input signal and generating an amplified output signal there from such that second and third order harmonics are substantially eliminated.

4. A method of enhancing power amplifier linearity, the method comprising the steps of:
applying a two-tone input signal to a power amplifier and generating a digitized output signal there from;
passing the digitized output signal through an inverse non-linear function signal processor and generating a feedback signal having intermodulation products less than fourth order there from;
converting the feedback signal to an analog signal; and
subtracting the feedback signal from the power amplifier input signal and generating an amplified output signal there from such that second and third order intermodulation products are substantially eliminated.

5. A method of enhancing power amplifier linearity comprising processing an input signal to the power amplifier such that non-linearity products associated with the power amplifier transfer function are substantially canceled prior to application of the input signal to the power amplifier.

6. The method according to claim 5, wherein the input signal is selected from the group consisting of a transmitted desired signal X, and a dedicated calibration signal.

7. The method according to claim 6, wherein the dedicated calibration signal is selected from the group consisting of a single tone signal, and a two tone signal.

8. The method according to claim 7, wherein the processing is non-decision directed.

9. The method according to claim 7, wherein the processing is decision directed.

10. The method according to claim 7, wherein the processing employs an open loop to estimate non-linear coefficients of the amplifier transfer function polynomial.

11. The method according to claim 10, wherein the processing further employs the non-linear coefficients to construct the amplifier transfer function inverse polynomial.

12. The method according to claim 11, wherein the processing further employs the amplifier transfer function inverse polynomial to substantially cancel the amplifier non-linearity products.

13. The method according to claim 12, further comprising the step of converting the processed signal to an analog signal prior to application of the input signal to the amplifier.

14. The method according to claim 7, wherein the processing employs a closed loop to estimate non-linear coefficients of the amplifier transfer function polynomial.

15. The method according to claim 14, wherein the processing further employs the non-linear coefficients to construct the amplifier transfer function inverse polynomial.

16. The method according to claim 15, wherein the processing further employs the amplifier transfer function inverse polynomial to substantially cancel the amplifier non-linearity products.

17. The method according to claim 16, further comprising the step of converting the processed signal to an analog signal prior to application of the input signal to the amplifier.

18. The method according to claim 5, wherein the non-linearity products comprise solely harmonic signals.

19. The method according to claim 5, wherein the non-linearity products comprise solely intermodulation products.

20. The method according to claim 5, wherein the non-linearity products comprise harmonic signals and intermodulation products.
